(19) United States
(12) Patent Application Publication
(10) Pub. No.: US 2014/0352767 A1
(43) Pub. Date: Dec. 4, 2014

(54) SOLAR CELL APPARATUS AND METHOD OF FABRICATING THE SAME

(71) Applicant: Dong Keun Lee, Seoul (KR)

(72) Inventor: Dong Keun Lee, Seoul (KR)

(73) Assignee: LG INNOTEK CO., LTD., Seoul (KR)

(21) Appl. No.: 14/351,813

(22) PCT Filed: Jun. 20, 2012
(86) PCT No.: PCT/KR2012/004887

§ 371 Date: Jun. 4, 2014

(30) Foreign Application Priority Data
Oct. 13, 2011 (KR) 10-2011-0104736

(51) Int. Cl. H01L 31/048; H01L 31/0236

(52) U.S. Cl. CPC H01L 31/048; H01L 31/02366
USPC 136/251

(57) ABSTRACT

Disclosed are a solar cell apparatus and a method of fabricating the same. The solar cell apparatus includes barrier parts provided in an outer region of a support substrate and provided in opposition to each other, a plurality of solar cells between the barrier parts, and a protective layer on the barrier parts and the solar cells.

### TECHNICAL FIELD

The embodiment relates to a solar cell apparatus and a method of fabricating the same.

### BACKGROUND ART

Solar cell apparatuses may be defined as devices to convert light energy into electrical energy by using a photovoltaic effect of generating electrons when light is incident onto a P-N junction diode. The solar cell apparatuses may be classified into a silicon solar cell apparatus, a compound semiconductor solar cell apparatus mainly including a group I-III-VI compound or a group III-V compound, a dye-sensitized solar cell apparatus, and an organic solar cell apparatus according to materials constituting the junction diode.

The minimum unit of the solar cell apparatus is a cell. In general, one cell generates a very small voltage of about 0.5V to about 0.6V. Therefore, a panel-shape structure of connecting a plurality of cells to each other in series on a substrate to generate voltages in the range of several voltages V to several hundreds of voltages V is referred to as a module, and a structure having several modules installed in a frame is referred to as a solar cell apparatus.

Typically, the solar cell apparatus has a structure of glass/filling material (ethylene vinyl acetate, EVA)/solar cell module/filling material (EVA)/surface material (back sheet).

In general, the glass includes low-iron tempered glass. The glass must represent high light transmittance and be treated to reduce the surface reflection loss of incident light. The EVA used as the filling material is interposed between the front/rear side of the solar cell and the back sheet to protect a fragile solar cell device. When the EVA is exposed to UV light for a long time, the EVA may be discolored, and the moisture proof performance of the EVA may be degraded. Accordingly, when the module is fabricated, it is important to select a process suitable for the characteristic of the EVA sheet so that the life span of the module can be increased, and the reliability of the module can be ensured. The back sheet is placed on a rear side of the solar cell module. The back sheet must represent superior adhesive strength between layers, must be easily handled, and must protect the solar cell device from an external environment.

The solar cell apparatus must have resistance against external moisture (H₂O) or external oxygen (O₂), and the problem related to the reliability must be solved in order to improve the performance of the solar cell apparatus. According to the related art, in order to solve the problem, a sealing treatment is performed with respect to the solar cell apparatus. However, even though the solar cell apparatus is sealed, moisture is infiltrated into the solar cell apparatus along the interfacial surface between a substrate and a sealing member, so that a solar cell electrode is corroded, thereby degrading the performance of the solar cell apparatus.

### DISCLOSURE OF INVENTION

### Technical Problem

The embodiment provides a solar cell apparatus capable of improving reliability and stability and a method of fabricating the same.

### Solution to Problem

According to the embodiment, there is provided a solar cell apparatus including barrier parts provided in an outer region of a support substrate and provided in opposition to each other, a plurality of solar cells between the barrier parts, and a protective layer on the barrier parts and the solar cells.

According to the embodiment, there is provided a method of fabricating a solar cell apparatus. The method includes forming solar cells, which include a back side electrode layer, a light absorbing layer, and a front side electrode layer sequentially formed, on a support substrate, forming a barrier part by patterning the solar cells, and forming a protective layer on the barrier part and the solar cells.

### Advantageous Effects of Invention

The solar cell apparatus according to the embodiment includes a barrier part with a predetermined pattern in an outer region of the support substrate. Accordingly, the embodiment cannot only extend the infiltration path of moisture (H₂O) or oxygen (O₂), but also increase the contact area with the protective layer formed on the barrier part.

Therefore, according to the solar cell apparatus of the embodiment, the infiltration of moisture or oxygen into the solar cell apparatus along the interfacial surface between the barrier part and the protective layer can be minimized. In addition, according to the solar cell apparatus of the embodiment, the solar cells can be effectively protected from moisture or oxygen, so that the stability and the reliability of the solar cell apparatus can be significantly ensured.

According to the method of fabricating the solar cell apparatus of the embodiment, an additional process of forming the barrier part is not required. Therefore, according to the method of fabricating the solar cell apparatus of the embodiment, the manufacturing cost and the time can be saved.

### BRIEF DESCRIPTION OF DRAWINGS

FIG. 1 is a sectional view showing a solar cell apparatus according to the embodiment;

FIGS. 2 and 3 are sectional views showing a barrier part according to the embodiment; and

FIGS. 4 to 8 are sectional views a method of manufacturing the solar cell apparatus according to the embodiment.

### MODE FOR THE INVENTION

In the description of the embodiments, it will be understood that when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

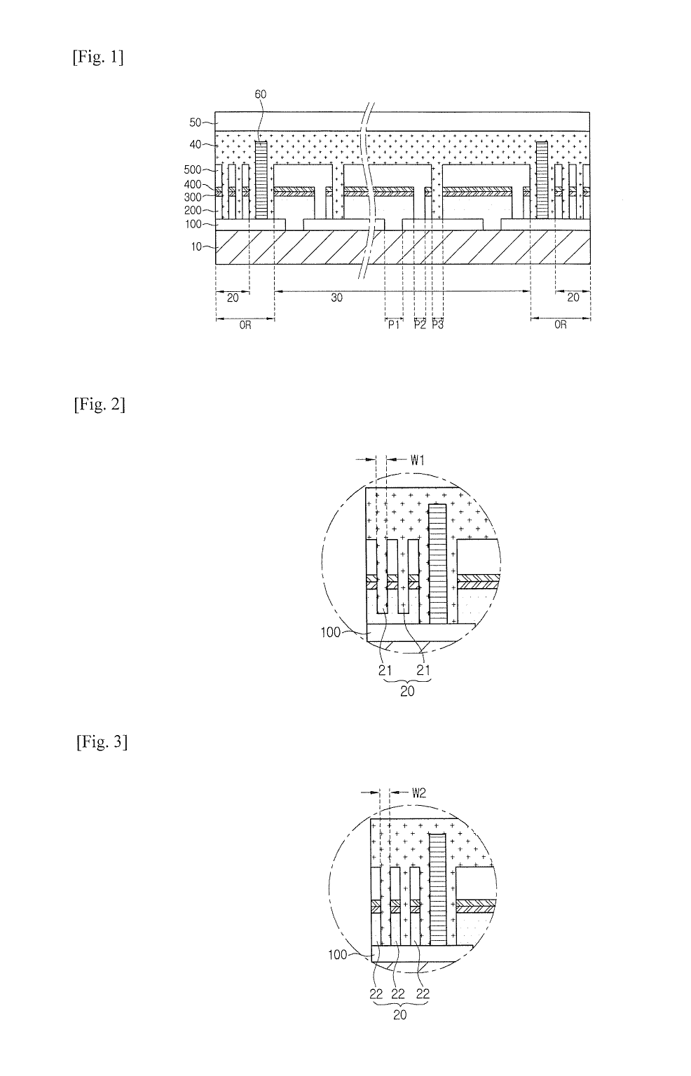

FIG. 1 is a sectional view showing a solar cell apparatus according to the embodiment, and FIGS. 2 and 3 are sectional views showing a barrier part according to the embodiment.

Referring to FIG. 1, the solar cell apparatus according to the embodiment includes a support substrate 10, a barrier part 20, a plurality of solar cells 30, a protective layer 40, a protective panel 50, and a bus bar 60.

The support substrate 10 has a plate shape and supports the solar cells 30, the protective layer 40, the protective panel 50, and the bus bar 60. The support substrate 10 may be transparent, and may be rigid or flexible. In addition, the support substrate 10 may include an insulator.

For example, the support substrate 10 may include a glass substrate, a plastic substrate, or a metallic substrate. In more detail, the support substrate 10 may include a soda lime glass substrate.

In addition, the support substrate 10 may include a ceramic substrate including alumina, stainless steel, or polymer having a flexible property.

The barrier part 20 is provided on the support substrate 10. In more detail, the barrier part 20 may be provided at an outer region OR of the support substrate 10. For example, the barrier part 20 may be provided in adjacent to both lateral sides of the support substrate 10. In addition, the barrier part 20 may extend with a long length in one direction, but the embodiment is not limited thereto.

The barrier part 20 may include a plurality of barrier parts. In more detail, the barrier part 20 may include two barrier parts. In this case, the barrier parts may be provided in opposition to each other as shown in FIG. 1.

In addition, the barrier part 20 may include four barrier parts. In this case, the barrier parts may surround four lateral sides of the outer region OR of the support substrate 10. In addition, the barrier parts may be integrally formed with each other, but the embodiment is not limited thereto.

The barrier part 20 is patterned. The barrier part 20 may have various patterns sufficient to extend the infiltration path of moisture or oxygen into the interfacial surface between the barrier part 20 and the protective layer 40 provided on the barrier part 20.

Referring to FIG. 2, the barrier part 20 may include a plurality of trench patterns 21. For example, the trench pattern 21 may have a width W1 of about 10 μm to about 100 μm. In more detail, the trench pattern 21 may have a width W1 of about 50 μm to about 100 μm, but the embodiment is not limited thereto. In addition, the trench pattern 21 may have various depths. For example, as shown in FIG. 2, the bottom surface of the trench pattern 21 may directly make contact with a light absorbing layer 200. In addition, the bottom surface of the trench pattern 21 may directly make contact with the support substrate 10. In other words, a portion of the support substrate 10 may be exposed by the trench pattern 21.

In addition, referring to FIG. 3, the barrier part 20 may include a plurality of protrusion patterns 22. For example, the sectional surface of the protrusion pattern 22 may be formed in the shape of a dot, a wire, a rod, a tube, or a concavo-convex pattern. In more detail, the protrusion pattern 22 may have the shape of the rod or the concavoconvex pattern. In addition, the interval between the protrusion patterns 22 may be in the range of about 10 μm to about 100 μm, in more detail, about 50 μm to about 100 μm, but the embodiment is not limited thereto.

The barrier part 20 may be formed in line with the solar cells 30. In other words, the barrier part 20 includes a back side electrode layer 100, a light absorbing layer 200, and a front side electrode layer 500 constituting the solar cells 30. In more detail, the barrier part 20 may include the back side electrode layer 100, the light absorbing layer 200, the buffer layer 300, the high resistance buffer layer 400, and the front side electrode layer 500, which are sequentially formed on the support substrate 10.

In other words, the barrier part 20 may be formed by laminating the same layers as layers constituting the solar cells 30 in a process of forming the solar cells 30. In addition, the barrier part 20 may be separated from the solar cells 30 through the following patterning process. Therefore, the barrier part 20 may be manufactured through the above-described simple process without an additional process of forming the barrier part.

As described above, according to the solar cell apparatus of the embodiment, the barrier part 20 has a pattern at the outer region OR of the support substrate 10. The barrier part 20 having the pattern not only can more extend the infiltration path of moisture (H₂O) or oxygen (O₂), but also increase the contact area with the protective layer 40 on the barrier part 20 when comparing with a barrier part without a pattern. Therefore, according to the solar cell apparatus of the embodiment, the moisture or the oxygen can be prevented from being infiltrated into the solar cell apparatus along the interfacial surface between the barrier part 20 and the protective layer 40.

The solar cells 30 are provided at a remaining region of the support substrate 10 except for the outer region OR. In more detail, the solar cells 30 may be interposed between the barrier parts 20.

A plurality of solar cells 30 are provided, and electrically connected to each other. For example, the solar cells 30 may be connected to each other in series, but the embodiment is not limited thereto. Therefore, a solar cell module can convert the sunlight into electrical energy.

The solar cells 30 include the back side electrode layer 100 on the support substrate 10, the light absorbing layer 200 on the back side electrode layer 100, and the front side electrode layer 500 on the light absorbing layer 200. The solar cells 30 may further include the buffer layer 300 and the high resistance buffer layer 400 interposed between the light absorbing layer 200 and the front side electrode layer 500, but the embodiment is not limited thereto.

The back side electrode layer 100 may include one selected from the group consisting of molybdenum (Mo), gold (Au), aluminum (Al), chrome (Cr), tungsten (W), and copper (Cu). Since the Mo among the materials makes a less thermal expansion coefficient difference from the support substrate 10 as compared with other elements, the Mo represents a superior adhesive property to prevent delamination.

The light absorbing layer 200 is provided on the back side electrode layer 100. The light absorbing layer 200 includes a group I-III-VI compound. For example, the light absorbing layer 200 may have the CIGSS (Cu(IN,Ga)(Se,S)₂) crystal structure, the CISS (Cu(IN)(Se,S)₂) crystal structure or the CGSS (Cu(Ga)(Se,S)₂) crystal structure.

The buffer layer 300 is provided on the light absorbing layer 200. The buffer layer 300 may include CdS, ZnS, InXSY or InXSeYZn(O, OH). The high resistance buffer layer 400 is provided on the buffer layer 300. The high resistance buffer layer 400 includes i-ZnO, which is not doped with impurities.

The front side electrode layer 500 may be provided on the light absorbing layer 200. For example, the front side electrode layer 500 may directly make contact with the high resistance buffer layer 400 on the light absorbing layer 200.

The front side electrode layer 500 may include a transparent conductive material. In addition, the front side electrode layer may have the characteristics of an N type semiconductor. In this case, the front side electrode layer 500 forms an N type semiconductor with the buffer layer 300 to make PN junction with the light absorbing layer 200 serving as a P type semiconductor layer.

The protective layer 40 is provided on the support substrate 10. In more detail, the protective layer 40 may be provided on the barrier part 20 and the solar cells 20 while directly making contact with the barrier part 20 and the solar cells 20. The pattern formed on the barrier part 20 may increase the contact area with the protective layer 40 formed on the barrier part 20. Therefore, according to the solar cell apparatus of the embodiment, moisture or oxygen can be prevented from being infiltrated into the solar cell apparatus along the interfacial surface between the barrier part 20 and the protective layer 40.

The protective layer 40 may be transparent and flexible. The protective layer 40 may include transparent plastic. In more detail, the protective layer 40 may include ethylenevinylacetate resin.

The protective panel 50 may be provided on the protective layer 40. The protective panel 50 protects the solar cells 30 from external physical shock and/or foreign matters. The protective panel 50 is transparent, for example, may include tempered glass.

Meanwhile, the solar cell apparatus according to the embodiment may include the bus bar 60 electrically connected to the solar cells 30. Referring to FIGS. 1 and 2, the bus bar 60 may be formed on the outer region OR of the support substrate 10. In more detail, the bus bar 60 may directly make contact with the back side electrode layer 100 formed on the support substrate 10. Meanwhile, the bus bar 60 may be formed on the solar cells 30. For example, the bus bar 60 may directly make contact with the front side electrode layer 500.

FIGS. 4 to 8 are sectional views showing a method of fabricating the solar cell apparatus according to the embodiment. Hereinafter, the method of fabricating the solar cell apparatus will be described by making reference to the description of the solar cell apparatus.

Referring to FIG. 4, the back side electrode layer 100 is formed on the support substrate 10. The back side electrode layer 100 may be formed through a PVD (Physical Vapor Deposition) scheme or a plating scheme.

The back side electrode layer 100 includes a first groove P1. In other words, the back side electrode layer 100 may be patterned in the first groove P1. In addition, the first groove P1 may have various shapes such as a stripe shape or a matrix shape as shown in FIG. 4. For example, the width of the first groove P1 may be in the range of about 80 μm to about 200 μm, but the embodiment is not limited thereto.

Referring to FIG. 5, the light absorbing layer 200, the buffer layer 300, and the high resistance buffer layer 400 are formed on the back side electrode layer 100. Thereafter, the light absorbing layer 200, the buffer layer 300, and the high resistance buffer layer 400 are formed therein with a second groove P2.

The light absorbing layer 200 may be formed through various schemes such as a scheme of forming a Cu(In,Ga)Se₂ (CIGS) based-light absorbing layer 200 by simultaneously or separately evaporating Cu, In, Ga, and Se and a scheme of performing a selenization process after a metallic precursor film has been formed.

Regarding the details of the selenization process after the formation of the metallic precursor layer, the metallic precursor layer is formed on the back side electrode 100 through a sputtering process employing a Cu target, an In target, or a Ga target. Thereafter, the metallic precursor layer is subject to the selenization process so that the Cu(In, Ga) Se₂ (CIGS) based-light absorbing layer 200 is formed.

In addition, the sputtering process employing the Cu target, the In target, and the Ga target and the selenization process may be simultaneously performed.

In addition, a CIS or a CIG light absorbing layer 200 may be formed through a sputtering process employing only Cu and In targets or only Cu and Ga targets and the selenization process.

Thereafter, the buffer layer 300 may be deposited on the light absorbing layer 200 through a CBD (Chemical Bath Deposition) scheme. In addition, ZnO is deposited on the buffering layer 300 through the sputtering process, thereby forming the high resistance buffer layer 400.

Referring to FIG. 5, the light absorbing layer 200, the buffer layer 300, and the high resistance buffer layer 400 are formed therein with a second groove P2. The second groove P2 may be mechanically formed, and a portion of the back side electrode layer 100 is exposed. The second groove P2 is formed by perforating the light absorbing layer 200. Accordingly, the second groove P2 may expose a top surface of the back side electrode layer 100. In addition, the width of the second groove P2 may be in the range of about 80 μm to about 200 μm, but the embodiment is not limited thereto.

Thereafter, as shown in FIG. 6, a transparent conductive material is laminated on the high resistance buffer layer 400 to form the front side electrode layer 500 serving as a second electrode and a connection wire 600. When laminating the transparent conductive material on the high resistance buffer layer 400, the transparent conductive material is filled in the second groove P2 to form the connection wire 600. The back side electrode layer 100 and the front side electrode layer 500 are electrically connected to each other by the connection wire 600.

The front side electrode layer 500 serves as a window layer to form PN junction with the light absorbing layer 200, and serves as a transparent electrode with respect to the whole surface of the solar cell apparatus. Accordingly, the front side electrode layer 500 may include zinc oxide (ZnO) representing high light transmittance and superior electrical conductivity.

In this case, the front side electrode layer 500 may have low resistance by doping Al on ZnO. For example, the front side electrode layer 500 may be formed through the RF sputtering process using the ZnO target, the reactive sputtering process using the Zn target or the organic metal chemical deposition process.

Thereafter, as shown in FIG. 6, a third groove P3 is formed by perforating the light absorbing layer 200, the buffer layer 300, the high resistance buffer layer 400, and the front side electrode layer 500. Unit cells C1, C2, C3, . . . , and Cn of the solar cell apparatus may be separated from each other by the third groove P3, and connected to each other by the connection wire 600. The third groove P3 may be formed through a mechanical scheme or by irradiating a laser beam, and may expose the top surface of the back side electrode layer 100.

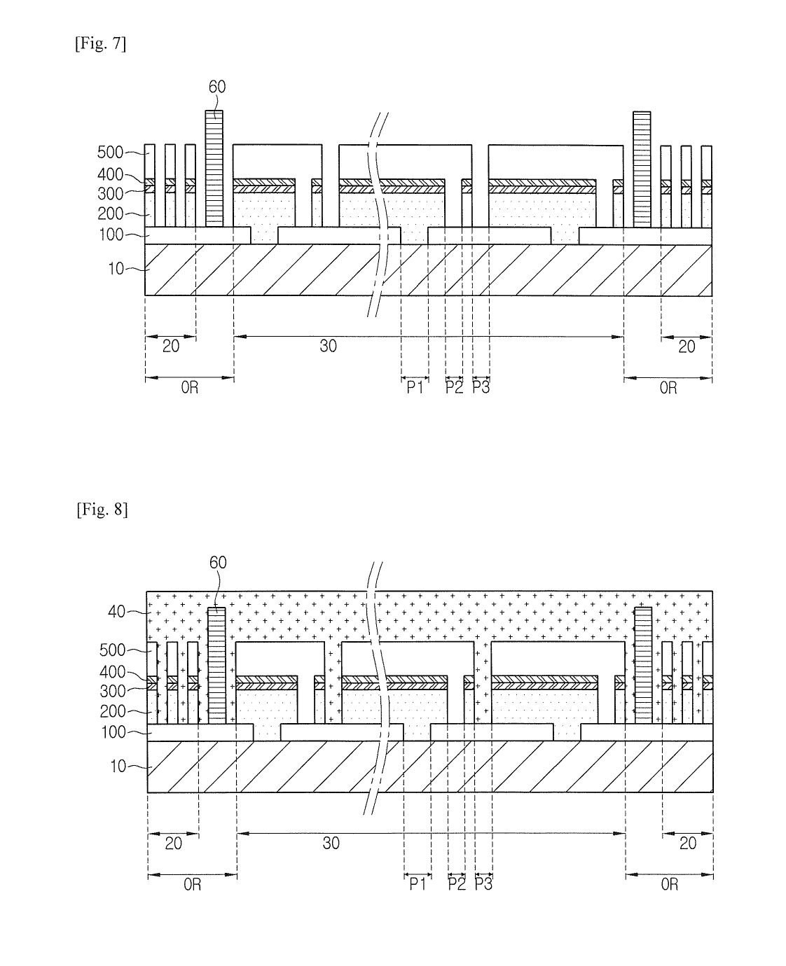

Referring to FIG. 7, the solar cells 30 are patterned to form the barrier part 20. In more detail, the barrier part 20 may be formed by patterning the solar cells 30 formed in the outer region OR of the support substrate 10. In other words, the barrier part 20 may be formed by selectively patterning the outermost solar cells 30.

For example, the barrier part 30 may be formed by performing a dry etching process or a wet etching process with respect to the solar cells 30. In more detail, the barrier part 30 may be formed through a mechanical scheme or may be formed by irradiating a laser beam, or may expose the top surface of the back side electrode layer 200.

Meanwhile, although the embodiment has been described in that the third groove P3 and the barrier part 30 are separately formed from each other, the embodiment is not limited thereto. In other words, the third groove P3 and the barrier part 30 can be simultaneously formed. In other words, the barrier part 20 is formed by laminating the same layers as layers constituting the solar cells 30 in the process of forming the solar cells 30, and may be separated from the solar cells 30 through the following patterning process. Therefore, the barrier part 20 may be manufactured through the above-described simple process without an additional process of forming the barrier part.

Thereafter, the bus bar 60 is formed on the support substrate 10. The bus bar 60 may be electrically connected to the solar cells 30. The bus bar 60 may be formed on the outer region OR of the support substrate 10 or may be formed on the front side electrode layer 500 of the solar cells 30, but the embodiment is not limited thereto.

The bus bar 60 may be formed through at least one deposition process such as a sputtering process by using a material selected from the group consisting of Ag, Cu, Au, Al, Sn, Ni, and the composition thereof.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell apparatus comprising:
barrier parts provided in an outer region of a support substrate in opposition to each other;
a plurality of solar cells between the barrier parts; and
a protective layer on the barrier parts and the solar cells.

2. The solar cell apparatus of claim 1, wherein each of the solar cells includes a back side electrode layer, a light absorbing layer, and a front side electrode which are sequentially formed on the support substrate.

3. The solar cell of claim 2, wherein each barrier part includes the back side electrode layer, the light absorbing layer, and the front side electrode layer.

4. The solar cell apparatus of claim 3, wherein the barrier part includes a plurality of trench patterns.

5. The solar cell apparatus of claim 4, wherein a portion of the light absorbing layer is exposed by each trench pattern.

6. The solar cell apparatus of claim 4, wherein each trench pattern has a width in a range of 10 μm to 100 μm.

7. The solar cell apparatus of claim 1, wherein each barrier part includes a plurality of protrusion patterns.

8. The solar cell apparatus of claim 7, wherein a sectional surface of each protrusion pattern includes a shape of a dot, a wire, a rod, a tube, or a concavo-convex pattern.

9. The solar cell apparatus of claim 7, wherein an interval between the protrusion patterns is in a range of 10 μm to 100 μm.

10. The solar cell apparatus of claim 1, further comprising a bus bar electrically connected to the solar cells.

11-19. (canceled)

20. The solar cell apparatus of claim 3, wherein the barrier part extend with a long length in one direction.

21. The solar cell apparatus of claim 4, wherein each trench pattern has a width in a range of 50 μm to 100 μm.

22. The solar cell apparatus of claim 7, wherein an interval between the protrusion patterns is in a range of 50 μm to 100 μm.

23. The solar cell apparatus of claim 1, wherein the barrier part is be formed in line with the solar cells.

24. The solar cell apparatus of claim 1, wherein the barrier part include a material equal to a material of the solar cell.
